(19) United States
(12) Patent Application Publication
(10) Pub. No.: US 2025/0040164 A1
(43) Pub. Date: Jan. 30, 2025

(54) METHOD FOR MANUFACTURING AN OHMIC CONTACT FOR A HEMT DEVICE

(71) Applicant: STMicroelectronics S.r.l., Agrate Brianza (IT)

(72) Inventors: Ferdinando IUCOLANO, Gravina Di Catania (IT); Cristina TRINGALI, Augusta (IT)

(73) Assignee: STMicroelectronics S.r.l., Agrate Brianza (IT)

(21) Appl. No.: 18/910,960

(22) Filed: Oct. 9, 2024

Related U.S. Application Data
(62) Division of application No. 16/697,051, filed on Nov. 26, 2019, now Pat. No. 12,154,967.

(30) Foreign Application Priority Data
Nov. 28, 2018 (IT) 102018000010656

(51) Int. Cl. H01L 29/66; H01L 29/20; H01L 29/778

(52) U.S. Cl. CPC H01L 29/66462; H01L 29/2003; H01L 29/7786; H01L 29/7787

(57) ABSTRACT

A method for manufacturing an ohmic contact for a HEMT device, comprising the steps of: forming a photoresist layer, on a semiconductor body comprising a heterostructure; forming, in the photoresist layer, an opening, through which a surface region of the semiconductor body is exposed at said heterostructure; etching the surface region of the semiconductor body using the photoresist layer as etching mask to form a trench in the heterostructure; depositing one or more metal layers in said trench and on the photoresist layer; and carrying out a process of lift-off of the photoresist layer.

### BACKGROUND

### Technical Field

The present disclosure relates to a method for manufacturing an ohmic contact for a field-effect transistor with high electron mobility, known as HEMT (High Electron Mobility Transistor). In particular, the present disclosure discusses a procedure for self-alignment of a gold-free ohmic contact, which can be applied, for example, to source contacts and drain contacts of the HEMT device.

### Description of the Related Art

As is known, a HEMT device comprises a heterostructure that has an interface between two different semiconductor materials, such as aluminum gallium nitride (AlGaN) and gallium nitride (GaN). When the HEMT device is appropriately biased, a layer of two-dimensional electron gas (2DEG) is induced at said interface.

The 2DEG layer represents an electron cloud with high charge density in which the charges possess high mobility. Such properties render the HEMT device attractive for radiofrequency (RF) applications and in power electronics.

Generally, the HEMT device comprises ohmic contacts for the source and drain terminals that are made of gold so as to enable low contact and access resistances to be achieved (c.f. Ferdinando Iucolano, Giuseppe Greco, and Fabrizio Roccaforte—Applied Physics Letters 103, 201604 (2013); doi: 10.1063/1.4828839).

The method for manufacturing gold ohmic contacts typically includes deposition of a sequence of metal layers on a semiconductor body formed by a stack including a substrate, a GaN layer and an AlGaN layer. The GaN and AlGaN layers form the heterostructure.

The above sequence of metal layers is obtained with known processes (such as lithographic and lift-off steps) and comprises a titanium (Ti) layer in contact with the surface of the semiconductor body, an aluminum (Al) layer on the titanium layer, a nickel (Ni) layer on the aluminum layer, and a deposition of gold (Au) on the nickel layer. The first three layers referred to above are adapted, in a known way, to promote adhesion of the gold (which functions as central body of the ohmic contact) to the semiconductor body.

The method for manufacturing gold ohmic contacts requires a thermal annealing process at high temperatures (for example, higher than 800° C.). In these temperature conditions, Ti reacts with the N₂ available in the GaN, to form titanium nitride. Charge transport is thus guided by a metal-like behavior of TiN due to intrusions of the metal in the 2DEG region. Formation of a gold contact is not in any case easy to implement on a CMOS line on account of the metallic contamination generated by gold, which would require dedicated equipment and segregated production areas.

A commonly used alternative approach is to resort to gold-free ohmic contacts, where the central body of the ohmic contact is made of titanium and aluminum.

The absence of gold in the ohmic contacts enables reduction of the annealing temperature to 600° C. and use of techniques such as rapid thermal annealing (RTA). In particular, the RTA technique reduces the mechanical stresses to which the semiconductor body with ohmic contact is subjected and prevents formation of states of charge trap, thus improving the efficiency and productivity of the manufacturing process and of the HEMT device itself.

Various ohmic-contact physical structures of the gold-free type are known in the prior art. In particular, two of them are illustrated, in a side section view, in FIGS. 1A and 1B.

FIG. 1A shows an ohmic-contact structure 4 in a HEMT device of a known type, with non-recessed semiconductor body 2 (Jing-Neng Yao, et al., “An Au-free GaN High Electron Mobility Transistor with Ti/Al/W Ohmic Metal Structure”, IEEE, 2015). A passivation layer 3, for example of SiN, extends over the semiconductor body 2 and in particular on the ohmic contact 4, to protect the latter.

FIG. 1B shows an ohmic-contact structure 6 in a HEMT device of a known type, with recessed semiconductor body 7 (W. H. Tham, et al., “AlxGa1 xN/GaN MISHEMTs with a common gold-free metal-stack for source/drain/gate”, IEEE ELECTRON DEVICE LETTERS, VOL. 36, No. 12, December 2015). A dielectric layer 8, for example of SiN, extends over the semiconductor body 7. The ohmic contact 6 extends through the dielectric layer 8.

The process for manufacturing the ohmic contact 6, recessed in the semiconductor body 7 (FIG. 1B) proves to be more complex than the process for obtaining the non-recessed ohmic-contact structure 4 (FIG. 1A). However, the electrical performance achieved by the HEMT device of the type illustrated in FIG. 1B proves to be higher than the electrical performance achieved by the HEMT device of FIG. 1A, and moreover presents better reproducibility and reliability.

In addition, the use of passivating material (here, SiN) for protecting the ohmic contacts 4 and 6 causes a greater dispersion of the values of contact resistance thereof.

### BRIEF SUMMARY

The aim of the present disclosure is to provide a method for manufacturing an ohmic contact for a HEMT device that will overcome the limitations of the prior art.

According to the present disclosure a method for manufacturing an ohmic contact for a HEMT device is provided.

### BRIEF DESCRIPTION OF THE SEVERAL VIEWS OF THE DRAWINGS

For a better understanding of the present disclosure, a preferred embodiment is now described purely by way of non-limiting example, with reference to the attached drawings, wherein:

FIGS. 1A and 1B show, in a side section views of a respective HEMT device with non-recessed ohmic contacts and with ohmic contacts recessed in a semiconductor body, respectively, according to embodiments of a known type;

FIGS. 2-6 show, in a side section view, manufacturing steps for obtaining a HEMT device with ohmic contact recessed in a semiconductor body, according to an embodiment of the present disclosure;

FIGS. 7-8 show intermediate structures that could be obtained according to the manufacturing steps of FIGS. 2-5; and

FIGS. 9A-12 show, in a side section view, manufacturing steps for obtaining a HEMT device with ohmic contact recessed in a semiconductor body, according to another embodiment of the present disclosure.

FIG. 13 is a side section view showing an HEMT device, according to one embodiment.

### DETAILED DESCRIPTION

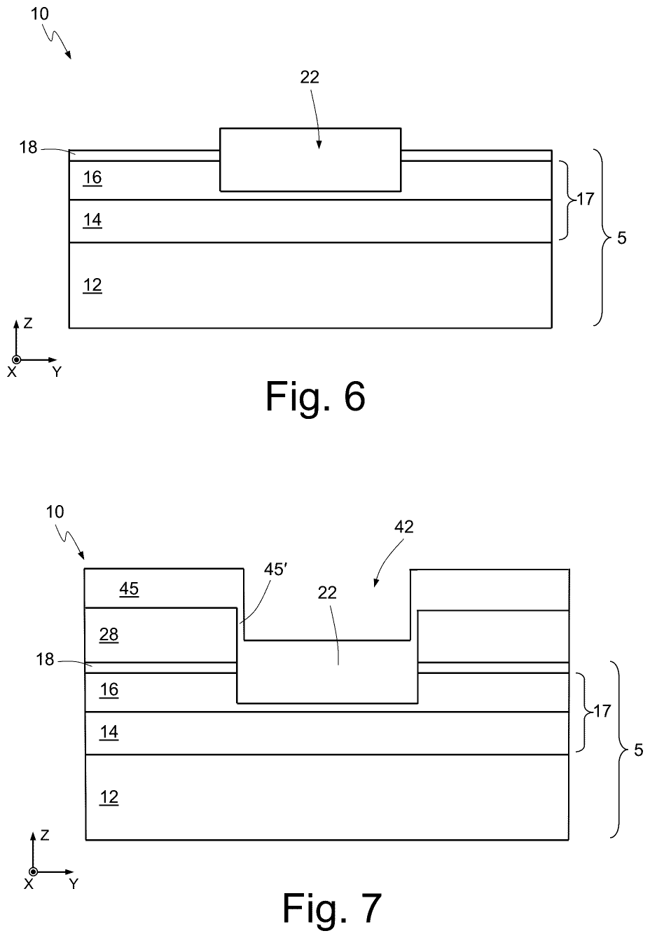

FIGS. 2-6 illustrate, in a side section view, in a triaxial cartesian reference system X, Y, Z, manufacturing steps for obtaining an ohmic-contact structure 10, of a recessed type, illustrated, as a whole, in FIG. 6. The structure 10 forms part of a HEMT device.

With reference to FIG. 2, a substrate 12 of semiconductor material, such as silicon, or silicon carbide (SiC), or sapphire (Al₂O₃), or some other material, is provided.

Formed on the substrate 12, in succession and in a way in itself known, along the direction of the axis Z are, respectively: a first structural layer 14, in particular of intrinsic gallium nitride (GaN) (channel layer of the HEMT device), grown, for example epitaxially, on the substrate 12; a second structural layer 16, in particular of intrinsic aluminum gallium nitride (AlGaN) or, more in general, of compounds based upon ternary or quaternary alloys of gallium nitride, such as AlxGa1-xN, AlInGaN, InxGa1-xN, AlxIn1-xAl (barrier layer of the HEMT device), grown, for example epitaxially, on the channel layer 14; and optionally a protection layer 18, in particular of GaN with a thickness of just a few nanometers (e.g., 1-4 nm), having the function of protecting the barrier layer 16 from oxidation phenomena.

The channel layer 14 and the barrier layer 16 form, in a way in itself known, a heterostructure 17.

In a way not illustrated in the Figure, between the substrate 12 and the channel layer 14 one or more further buffer layers may be present.

The channel layer 14 has a thickness (along the axis Z), for example approximately between 1 μm and 5 μm; the barrier layer 16 has a thickness (along the axis Z), for example approximately between 5 nm and 30 nm.

A 2DEG layer 15 is formed at the interface between the channel layer 14 and the barrier layer 16. The charge carriers belonging to the 2DEG are free to move in any direction in a plane XY (defined by the axes X and Y) at the 2DEG interface 15, whereas they are confined along the axis Z.

The substrate 12, the channel layer 14, the barrier layer 16, and the protection layer 18 form a semiconductor body 5.

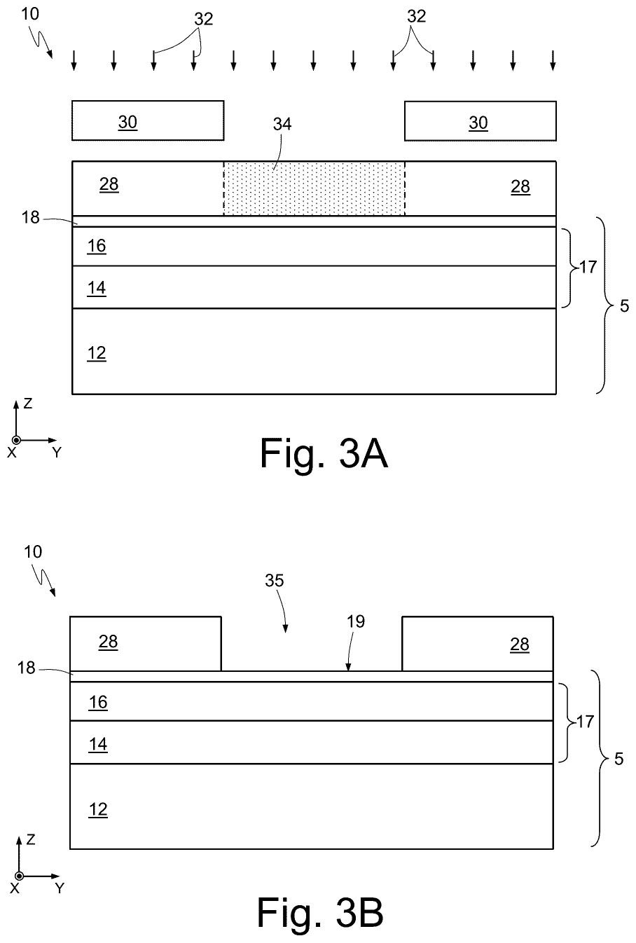

With reference to FIG. 3A, a photoresist layer 28, with a thickness, for example, of between 1 and 3 μm is deposited. Said photoresist layer 28 entirely and evenly coats the epitaxial layer 18.

This is then followed by a step of photolithographic exposure (represented by the arrows 32) of the photoresist layer 28, via the use of a mask 30. The regions of the photoresist layer 28 not covered by the mask 30 thus become soluble during the subsequent etching step.

The mask 30 is such that a region 34 of the photoresist layer 28 is exposed. Said region 34 defines the region in which the ohmic contact will be provided.

Then (FIG. 3B), the mask 30 is removed, and an etching step (e.g., of a wet type) is carried out for selective removal of the region 34 of the photoresist layer 28. A trench 35 is thus formed in the photoresist layer 28, through which a surface portion 19 of the protection layer 18 is exposed.

The photolithographic steps listed above have been described with reference to a positive photoresist. A different embodiment, not illustrated, envisages the use of a negative photoresist to form the trench 35 in the photoresist layer 28 with appropriate modifications to the photolithographic mask used, in a way in itself evident to the person skilled in the art.

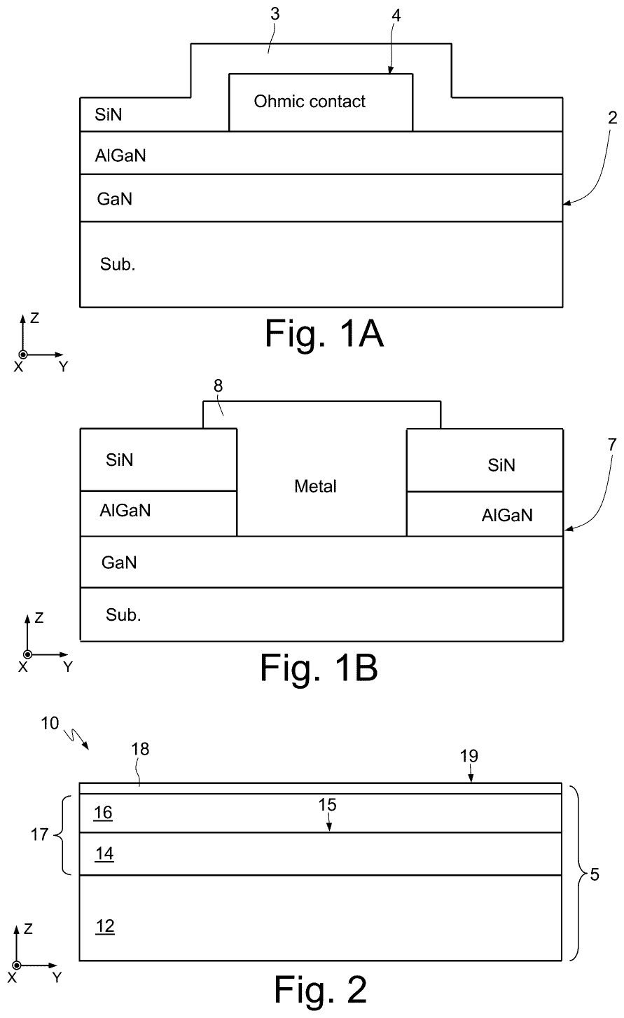

It may be noted that the process described with reference to FIGS. 1-3B does not require deposition of a layer of passivating material (such as silicon nitride), as typically envisaged by the prior art.

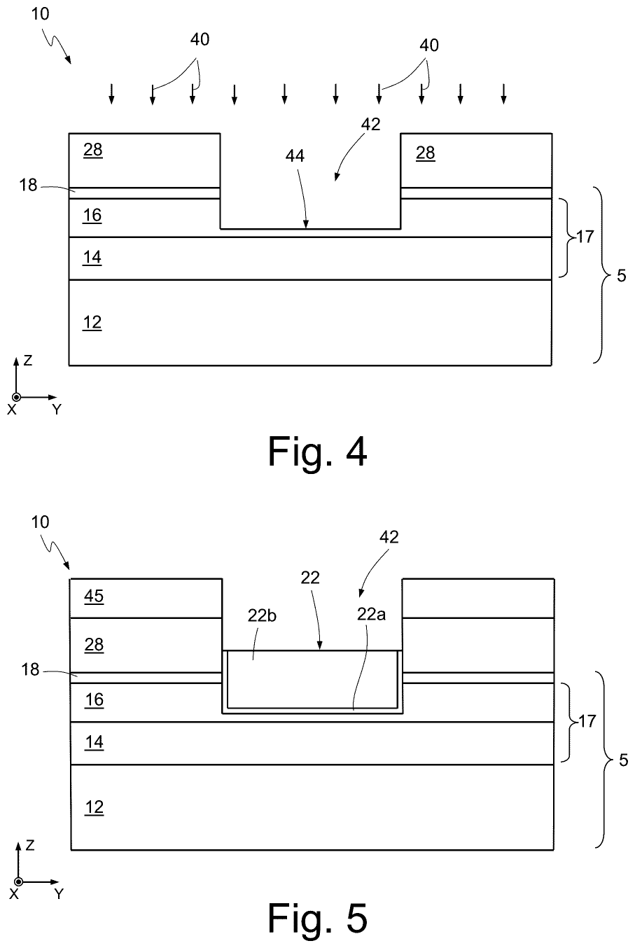

With reference to FIG. 4, an etch is then carried out (represented by arrows 40) for selective removal of portions of the protection layer 18 and of the underlying barrier layer 16, which are exposed through the trench 35. More in particular, the etching process comprises a first step, for removing the protection layer 18, and a second step, for partly or completely removing the barrier layer 16. Both of these steps use a Cl₂-based chemistry.

The photoresist layer 28 functions as an etching mask, for protecting the regions of the semiconductor body 5 not exposed through the trench 35.

At the trench 35, the semiconductor body 5 is then etched further, to form a contact trench 42, which extends in depth in the barrier layer 16, terminating inside the barrier layer 16 itself. The contact trench 42 is delimited underneath by a bottom surface 44 of the barrier layer 16.

The contact trench 42 is adapted to house an ohmic contact, as described hereinafter.

With reference to the etching process 40, the first etching step is designed to remove the protection layer 18 throughout its entire thickness in the area exposed by the trench 35, whereas the second etching step is designed to remove only part of the thickness, along Z, of the barrier layer 16. It is evident that, in the absence of the protection layer 18, which is optional, the etching process 40 comprises a single etching step for removing selective portions of the barrier layer 16.

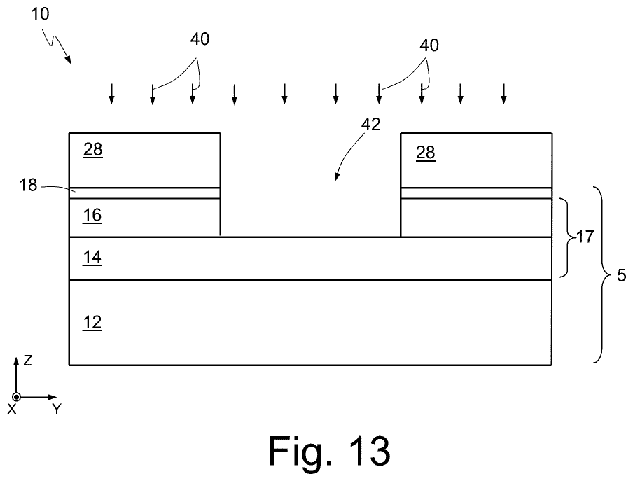

It is moreover evident that, in other embodiments, the contact trench 42 may extend throughout the entire thickness of the barrier layer 16, terminating at the interface with the underlying layer (here, the channel layer 14), or else proceeding into the underlying layer, according to the design needs and parameters. The embodiment of termination of the contact trench 42 at the interface with the channel layer 14 is shown in FIG. 13.

With reference to FIG. 5, there then follows deposition of one or more layers of conductive material, in particular one or more metal layers, via known techniques, such as sputtering or evaporation. In particular, a stack of metal layers is formed (three of which are illustrated in FIGS. 5 and 6) adapted to form an ohmic contact 22.

Formation of the stack of metal layers comprises, according to one embodiment, forming a first interface layer 22a and a filling layer 22b on the interface layer 22a. The interface layer 22a is made of a material chosen from titanium or tantalum. The filling layer 22b is, in particular, made of aluminum.

Formation of the stack of metal layers comprises, according to a further embodiment, forming in succession a first titanium or tantalum layer, an aluminum layer, and a second layer, which is also made of titanium or tantalum. The Ti layer is adapted to promote the adhesion of the nickel or tungsten layer to the bottom surface 44 of the contact trench 42 (i.e., to the barrier layer 16) and has the function of interface layer 22a. The Al layer functions, instead, as filling layer 22b, or central body, of the ohmic contact 22. The last Ti or Ta layer serves as packaging layer.

It is evident that other materials, or a different number of layers, may be used to form the stack of the ohmic contact 22, according to the design specifications. For instance, it is possible to omit the interface layer 22a by depositing just the filling layer 22b, which, in this case, is made of aluminum.

The one or more conductive materials for formation of the ohmic contact 22 are both deposited inside the trench 42 and on the outside thereof, over the photoresist layer 28, which is thus covered at the top by a spurious metal deposition 45.

This is followed by a lift-off step, for removing both the photoresist layer 28 and the spurious metal material 45.

A step of rapid thermal annealing (RTA) is then carried out, which enables perfecting of the ohmic contact, in a way in itself known. This procedure is conducted at a temperature ranging between approximately 450° C. and approximately 650° C., in protected environment (for example, in a nitrogen or argon atmosphere).

FIG. 6 shows the structure 10 at the end of the manufacturing steps described, which includes the recessed gold-free ohmic contact 22.

As may be seen, the ohmic contact 22 is automatically aligned, or self-aligned, to the recessed region formed previously in the heterostructure 17.

This result is achieved by using the same photoresist layer 28 in two different steps of the manufacturing process. Firstly, the photoresist layer 28 is used during etching 40 as a mask for creation of the contact trench 42 (and hence for defining the recessed region in the heterostructure 17). Moreover, the photoresist layer 28 is used as a further mask for forming the ohmic contact 22, by deposition of metal material.

FIG. 7 shows a possible arrangement following the deposition of the one or more metal layers to create the ohmic contact 22 and the spurious metal material 45. The arrangement of FIG. 7 is similar to the arrangement of FIG. 5 except for the addition of spurious metal material 45′, sometimes referred to as “dog ears,” along the sidewalls of the photoresist layer 28. Such spurious metal material 45′ is a possible artifact of the metal deposition, such as sputtering or evaporation, of the one or more metal layers of the ohmic contact 22. Such spurious metal material 45′ is undesirable because its connection to both the spurious metal material 45 and the ohmic contact 22 would prevent lift-off of the spurious metal material 45 and/or damage the ohmic contact 22.

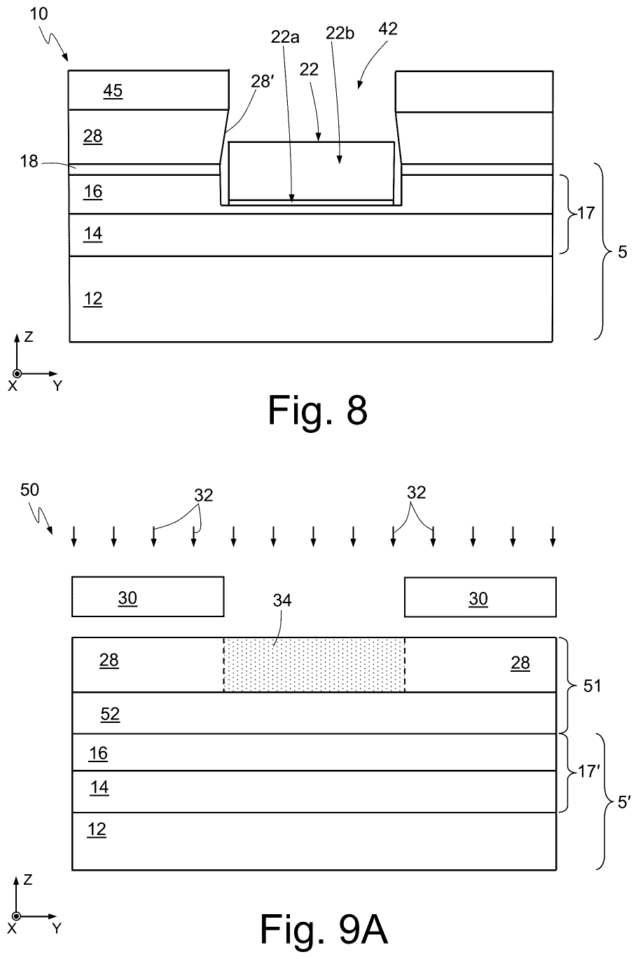

To avoid formation of the spurious metal material 45′ along the sidewalls of the photoresist layer 28, one could form the photoresist layer with inclined sidewalls 28′ as shown in FIG. 8. The deposition, such as by evaporation, of the one more layers to form the ohmic contact 22 is typically performed substantially vertically. As a result, the overhang of the inclined sidewalls 28′ would enable the ohmic contact 22 to be formed in the contact trench 42 without contacting the inclined sidewalls 28′ or the sidewalls of the layers 16, 18, and thus, without forming the spurious metal material 45′ along the sidewalls of any of the layers 16, 18, 28. As a result, the lift-off of the spurious metal material 45 and photoresist layer 28 may proceed without damage to the ohmic contact 22. The ohmic contact 22 includes the thinner first interface layer 22a and the thicker filling layer 22b.

A problem with the arrangement shown in FIG. 8 is that control of the process for forming the inclined sidewalls 28′ is difficult and would need to be very precise.

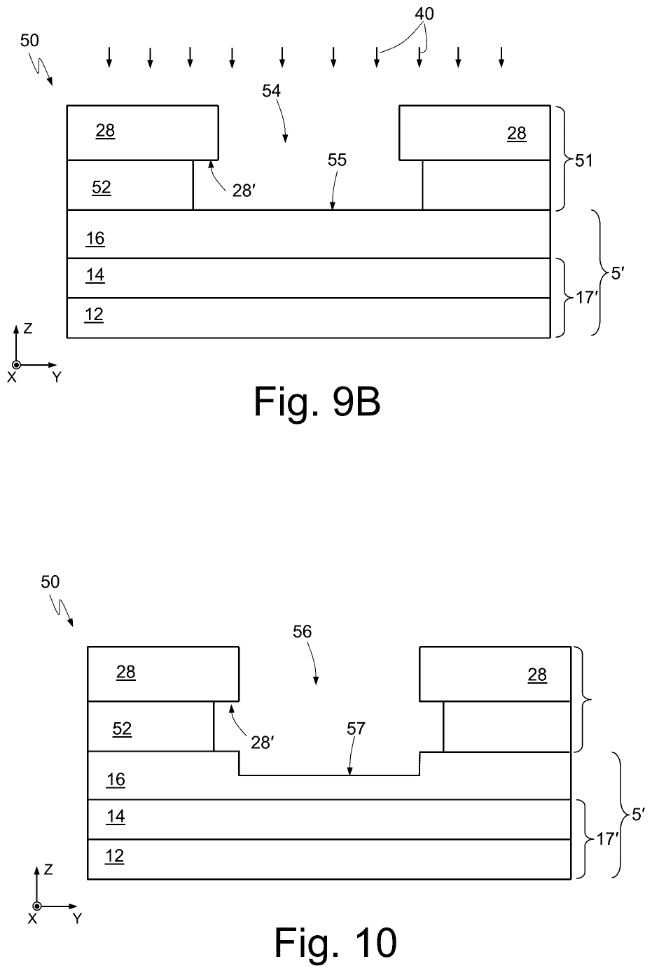

FIGS. 9A-12 illustrate manufacturing steps for obtaining an ohmic-contact structure 50 according to another embodiment of the disclosure.

With reference to FIG. 9A, the structure 50 includes a semiconductor body 5′ formed by the semiconductor substrate 12 and a heterostructure 17′. The heterostructure 17′ is formed by the channel layer 14 and the barrier layer 16. As in the embodiment of FIGS. 2-6, the semiconductor body 5′ could optionally include a protection layer, like the protection layer 18, for protecting the barrier layer.

Deposited on the semiconductor body 5′ is a bilayer 51 that includes an underlayer 52 and the photoresist layer 28. The underlayer 52 may have a thickness slightly higher than the thickness of the evaporated metal, for example, of between 0.6 and 1.5 μm. The underlayer 52 may be a solution of organic polymer, such as SF11 or SF09, that is spun on the semiconductor body 5′, or may be any other material that is etchable by the developer that is used to etch the photoresist layer 28.

The deposition of the bilayer 51 is followed by the step of photolithographic exposure (represented by the arrows 32) of the photoresist layer 28, via the use of the mask 30. The regions 34 of the photoresist layer 28 not covered by the mask 30 thus become soluble during the subsequent etching step.

In FIG. 9B the mask 30 is removed, and an etching step (e.g., of a wet type) is carried out for selective removal of the region 34 of the photoresist layer 28 and a portion of the underlayer 52. A trench 54 is thus formed through the photoresist layer 28 and the underlayer 52, through which a surface portion 55 of the semiconductor body 5′ is exposed. Forming the underlayer 52 of a material that is etchable by the developer that is used to remove the region 34 of the photoresist layer 28 and using a wet developer enables a portion 28′ of the photoresist layer 28 to overhang a remaining portion of the underlayer 52.

The photolithographic steps listed above have been described with reference to a positive photoresist. A different embodiment, not illustrated, envisages the use of a negative photoresist to form the trench 54 with appropriate modifications to the photolithographic mask used, in a way in itself evident to the person skilled in the art.

It may be noted that the process described with reference to FIGS. 9A-9B does not require deposition of a layer of passivating material (such as silicon nitride), as typically envisaged by the prior art.

With reference to FIG. 10, an etch is then carried out (represented by arrows 40) for selective removal of a portion of the barrier layer 16, which is exposed through the trench 54. As with the method of FIGS. 2-6, the barrier layer 16 may be etched partially or completely through. The etch is preferably a dry etch such that the portions of the semiconductor body 5′ covered by the overhanging portion 28′ of the photoresist layer 28 are protected from etching

The etching of the semiconductor body 5′ at the trench 54 forms a contact trench 56, which extends in depth in the barrier layer 16, terminating inside the barrier layer 16 itself. The contact trench 56 is delimited underneath by a surface 57 of the barrier layer 16.

It is moreover evident that, in other embodiments, the contact trench 56 may extend throughout the entire thickness of the barrier layer 16, terminating at the interface with the underlying layer (here, the channel layer 14), or else proceeding into the underlying layer.

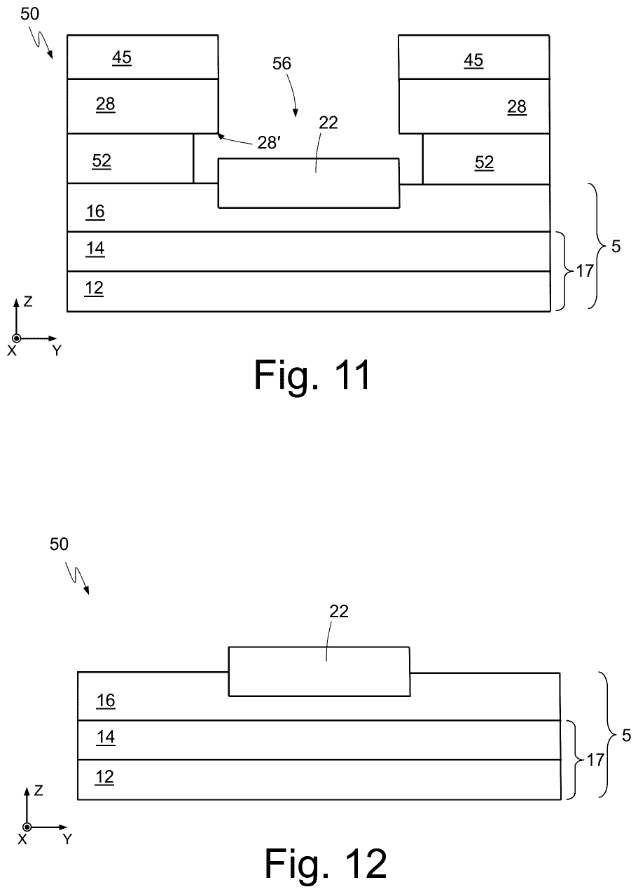

With reference to FIG. 11, there then follows deposition of one or more layers of conductive material, in particular one or more metal layers, via known techniques, such as sputtering or evaporation. In particular, the deposition forms the ohmic contact 22, which may include the layers 22a, 22b as discussed above.

The one or more conductive materials for formation of the ohmic contact 22 are both deposited inside the trench 56 and on the outside thereof, over the photoresist layer 28, which is thus covered at the top by the spurious metal deposition 45. Due to the presence of the overhanging portion 28′ of the photoresist layer 28, which acts as a mask, the ohmic contact 22 is formed on the surface 57 of the barrier layer 16 and is spaced apart from the sidewalls of the underlayer 52. Further, due to the presence of the underlayer 52 and the vertical orientation of the sidewalls of the photoresist layer 28, no spurious metal material is formed on those sidewalls, in contrast to the spurious metal material 45′ shown in FIG. 7.

The formation of the ohmic contact 22 is followed by a lift-off step, for removing both the underlayer 52, the photoresist layer 28 and the spurious metal material 45. FIG. 12 shows the structure 20 at the end of the manufacturing steps described, which includes the recessed gold-free ohmic contact 22.

As may be seen, the ohmic contact 22 is automatically aligned, or self-aligned, to the recessed region formed previously in the heterostructure 17.

This result is achieved by using the same photoresist layer 28 in two different steps of the manufacturing process. Firstly, the photoresist layer 28 is used during etching 40 as a mask for creation of the contact trench 56 (and hence for defining the recessed region in the heterostructure 17). Moreover, the photoresist layer 28 is used as a further mask for forming the ohmic contact 22, by deposition of metal material.

From an examination of the characteristics of the disclosure provided according to the present disclosure the advantages that it affords are evident.

In particular it is possible to obtain gold-free ohmic contacts that present lower contact and access resistances, and the electrical performance of which is highly reproducible.

The manufacturing process is simplified via the use of the photoresist layer as mask both during the etching step and during metal deposition of the ohmic contact. The ohmic contact is thus automatically aligned with the recessed AlGaN region. This enables better electrical performance to be achieved by the HEMT device and reduction of the related production costs, as well as guaranteeing structural quality of the ohmic contact.

Having a low contact resistance enables a higher maximum current through the HEMT device, and hence a higher output power, to be obtained.

A low contact resistance is moreover fundamental in radiofrequency applications for improving the frequency response of the HEMT device.

According to the present disclosure, a passivation layer is not necessary for formation of the metal contact. The absence of passivating material in the process for manufacturing the ohmic contact enables a lower spread of the values of contact resistance to be obtained, thus improving the electrical properties of the HEMT device.

The disclosure described herein hence reduces the costs for manufacturing the ohmic contacts, rendering the manufacturing process compatible with CMOS technology.

Finally, it is clear that modifications and variations may be made to the disclosure described and illustrated herein, without thereby departing from the scope of protection thereof.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An intermediate structure for making a high electron mobility transistor (HEMT) device, comprising:
a semiconductor body that includes a heterostructure;
an underlayer on the heterostructure;
a photoresist layer on the underlayer;
an opening that extends completely through the photoresist layer and the underlayer and into the heterostructure, the opening including a trench in the heterostructure and extending further laterally in the underlayer than in the photoresist layer such that the photoresist layer includes overhang portions extending beyond the underlayer; and
an ohmic contact formed in the trench.

2. The intermediate structure according to claim 1, wherein the ohmic contact includes sidewalls that are aligned with sidewalls of the overhang portions of the photoresist layer.

3. The intermediate structure according to claim 1, wherein the one or more metal layers comprises a stack including a metal interface layer in contact with said heterostructure and a metal filling layer on the metal interface layer.

4. The intermediate structure according to claim 3, wherein forming the metal interface layer includes a layer of a material chosen from titanium and tantalum; and the metal filling layer includes an aluminum layer.

5. The intermediate structure according to claim 1, wherein the semiconductor body comprises a substrate, a channel layer on the substrate, and a barrier layer on the channel layer, the trench extending through part of the barrier layer or throughout a thickness of the barrier layer.

6. The intermediate structure according to claim 1, wherein the ohmic contact is spaced apart from sidewalls of the underlayer.

7. A device, comprising:
a semiconductor body including:
a substrate;
a gallium nitride layer on the substrate having a first surface opposite a second surface along a first direction; and
a barrier layer on the gallium nitride layer, the barrier layer having a first surface opposite a second surface along the first direction, the second surface of the barrier layer being directly on the first surface of the gallium nitride layer;
a protection layer on the first surface of the barrier layer;
a photoresist layer on the protection layer, the photoresist layer having a first surface opposite a second surface along the first direction, the second surface being directly on the protection layer;
a trench extending along the first direction entirely through the photoresist layer and the protection layer, the trench extending partially through the barrier layer and terminating between the first and second surface of the barrier layer, the trench including:
a first plurality of inclined sidewalls extending along a second direction transverse to the first direction from the first surface of the photoresist layer to the second surface of the photoresist layer; and
a second plurality of sidewalls extending along the first direction entirely through the protection layer and partially through the barrier layer; and
a stack of metal layers in the trench directly on the barrier layer, the stack including:
an interface layer having a first thickness along the first direction; and
a filling layer on the interface layer having a second thickness along the first direction greater than the first thickness, at least a portion of the interface layer and the filling layer being between the first and second surfaces of the barrier layer along the first direction.

8. The device according to claim 7, further comprising a metal layer on the first surface of the protection layer, first trench extending entirely through the metal layer.

9. The device according to claim 8, further comprising a third plurality of sidewalls of the trench extending along the first direction from a first surface of the metal layer to a second surface opposite the first surface of the metal layer.

10. The device according to claim 7, wherein the protection layer is gallium nitride.

11. The device according to claim 7, wherein the barrier layer is aluminum gallium nitride, the barrier layer being in direct contact with the gallium nitride layer and the protection layer.

12. The device according to claim 7, wherein the entire interface layer is between the first surface and the second surface of the barrier layer along the first direction.

13. The device according to claim 7, wherein the stack of metal layers is entirely physically separated from photoresist layer and the protection layer.

14. The device according to claim 13, wherein the filling layer is entirely physically separated from the barrier layer.

15. The device according to claim 7, wherein the stack of metal layers includes a plurality of sidewalls extending along the first direction.

16. A device, comprising:
a heterostructure including:
a gallium nitride layer; and
a barrier layer having a first surface opposite a second surface along the first direction, the second surface of the barrier layer being directly on the gallium nitride layer;
a protection layer on the first surface of the barrier layer;
a photoresist layer having a first surface opposite a second surface along the first direction, the second surface being directly on the protection layer;
an opening extending along the first direction through the photoresist layer and the protection layer to a first depth between the first and second surface of the barrier layer, the opening including:
a first plurality of inclined sidewalls transverse to the first direction extending from the first surface of the photoresist layer to the second surface of the photoresist layer; and
a second plurality of sidewalls extending along the first direction entirely through the protection layer to the first depth; and
an ohmic contact in the trench directly on the barrier layer, the ohmic contact including:
an interface layer; and
a filling layer on the interface layer having a second thickness along the first direction greater than the first thickness, the entire interface layer being between the first surface and the second surface of the barrier layer along the first direction, the ohmic contact being entirely physically separated from the first plurality of inclined sidewalls and the second plurality of sidewalls.

17. The device according to claim 16, wherein the gallium nitride layer has a thickness along the first direction in the range of 1 and 5 microns and the barrier layer has a thickness along the first direction in the range of 5 and 30 microns.

18. The device according to claim 16, wherein the interface layer has a first thickness along the first direction and the filling layer has a second thickness along the first direction greater than the first thickness.

19. The device according to claim 16, further comprising:
a metal layer on the first surface of the protection layer, opening extending entirely through the metal layer, and
a third plurality of sidewalls of the trench extending along the first direction from a first surface of the metal layer to a second surface opposite the first surface of the metal layer.

20. The device according to claim 19, wherein the opening has a first width along a second direction between the second plurality of sidewalls and the opening has a second width along the second direction between the third plurality of sidewalls, the first width being greater than the second width.
